(19) United States
(12) Patent Application Publication
(10) Pub. No.: US 2017/0317225 A1
(43) Pub. Date: Nov. 2, 2017

(54) SYSTEM AND METHOD FOR ALL WRAP AROUND POROUS SILICON FORMATION

(71) Applicant: APPLIED MATERIALS, INC., Santa Clara, CA (US)

(72) Inventors: Takao YONEHARA, Sunnyvale, CA (US); Pravin K. NARWANKAR, Sunnyvale, CA (US); Jonathan S. FRANKEL, San Jose, CA (US)

(21) Appl. No.: 15/532,001

(22) PCT Filed: Dec. 7, 2015
(86) PCT No.: PCT/US2015/064194

§ 371 Date: May 31, 2017

Related U.S. Application Data
(60) Provisional application No. 62/090,213, filed on Dec. 10, 2014.

(51) Int. Cl. H01L 31/18; H01L 21/683

(52) U.S. Cl. CPC H01L 31/1804; H01L 31/1876; H01L 21/6833; H01L 21/6838

(57) ABSTRACT

Methods and systems for all wrap around porous silicon formation are provided herein. In some embodiments, a substrate holder used for all wrap around porous silicon formation may include a body having a tapered opening along a first edge of the body, wherein the tapered opening is configured to release byproduct gases produced during porous silicon formation on a substrate supported by the substrate holder, a first vacuum channel formed in the body and extending to a first surface of the body, and a first sealing element disposed on the first surface of the body and fluidly coupled to the first vacuum channel, where in the first sealing element supports the substrate when disposed thereon.

### FIELD

Embodiments of the present disclosure generally relate to semiconductor processing, and more specifically, to methods and apparatus for forming porous silicon layers.

### BACKGROUND

Crystalline silicon (including multi- and mono-crystalline silicon) is the most dominant absorber material for commercial solar photovoltaic (PV) applications, currently accounting for well over 80% of the solar PV market. There are different known methods of forming monocrystalline silicon film and releasing or transferring the grown semiconductor (e.g., monocrystalline silicon) layer. Regardless of the methods, a low cost epitaxial silicon deposition process accompanied by a high-volume, production-worthy low cost method of release-layer formation are prerequisites for wider use of silicon solar cells.

Porous silicon (PS) formation is a fairly new field with an expanding application landscape. Porous silicon is created by the electrochemical etching of silicon (Si) template substrates with appropriate doping in an electrolyte bath. The electrolyte for porous silicon is: hydrogen fluoride (HF) (49% in H2O typically), isopropyl alcohol (IPA) (and/or acetic acid), and deionized water (DI H2O). IPA (and/or acetic acid) serves as a surfactant and assists in the uniform creation of porous silicon. Additional additives such as certain salts may be used to enhance the electrical conductivity of the electrolyte, thus reducing its heating and power consumption through ohmic losses.

Porous silicon has been used as a sacrificial layer in MEMS and related applications, where there is a much higher tolerance for cost per unit area of the substrate and resulting product than solar PV. Typically porous silicon is produced on simpler and smaller single-substrate electrochemical process chambers with relatively low throughputs on smaller substrate footprints. Currently there is no commercially available porous silicon equipment that allows for a high throughput, cost effective porous silicon manufacturing. The viability of this technology in solar PV applications hinges on the ability to industrialize the process to large scale (at much lower cost), requiring development of very low cost-of-ownership, high-productivity porous silicon manufacturing equipment.

Another major cost is the starting Si template substrate itself. The starting Si template substrate may be highly doped with boron to control the porous Si properties, such as, for example, thickness, and porosity including pore size, distribution and density. One approach to dilute the cost of the template is to reuse the template multiple times after reclaiming the substrate surface and addressing edge irregularity issues after exfoliating the epitaxial layer from the top and bottom of the template substrate. In addition, portions of the substrate edge may not be anodized during batch processing, resulting in no porous Si layer formed throughout at the edge of the substrate. The lack of porous Si layer formed on portions of the substrate edge locks the epitaxial layers on those portions.

In order to reuse such substrates with edge irregularities, additional edge treatment is necessary with additional cost. Conventional edge mechanical beveling and edge polishing are utilized by the substrate manufactures to provide the round shaped semiconductor substrates for various kinds of the devices and integrated circuits. This method is well established for smooth edge quality in the high yield, however, it is reasonably costly. For PV applications, square substrates are normally used to process PV cells and the surface and edge quality is much inferior to round semiconductor substrates.

Thus, the inventors have provided methods and apparatus for forming porous silicon layers with high throughput at high volume with decreased cost.

### SUMMARY

Methods and systems for all wrap around porous silicon formation are provided herein. In some embodiments, a substrate holder used for all wrap around porous silicon formation may include a body having a tapered opening along a first edge of the body, wherein the tapered opening is configured to release byproduct gases produced during porous silicon formation on a substrate supported by the substrate holder, a first vacuum channel formed in the body and extending to a first surface of the body, and a first sealing element disposed on the first surface of the body and fluidly coupled to the first vacuum channel, where in the first sealing element supports the substrate when disposed thereon.

In some embodiments, electrochemical reaction system for all wrap around porous silicon formation may include a reaction tank configured to hold a liquid chemical solution to anodize one or more substrates, a plurality of substrate holders disposed in the reaction tank, each holder configured to retain a substrate when disposed thereon via vacuum chucking forces, a first electrode disposed at a first end of the reaction tank, a second electrode disposed at a second end of the reaction tank opposite the first end, and a chemical overflow system configured to collect overflow reaction chemicals during substrate processing.

In some embodiments, a method for all wrap around porous silicon formation may include disposing a plurality of silicon substrates onto a corresponding plurality of substrate holders disposed in a reaction tank filled with a hydrogen fluoride (HF) solution of a electrochemical reaction system, retaining each of the plurality of silicon substrates on a first side of a corresponding substrate holder via vacuum chucking, providing a current through the hydrogen fluoride (HF) solution using a positive and negative electrode disposed in the reaction tank, forming a first porous silicon layer on a first surface each of the plurality of silicon substrates, where the first surface of the silicon substrate faces the negative electrode, repositioning each of the plurality of silicon substrates to expose a second surface of the silicon substrates to the negative electrode, and forming a second porous silicon layer on a second surface of the silicon substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIGS. 1A-1D depict a general overview of a process and substrate carrier assembly for fully covering substrate surfaces with porous Si in accordance with some embodiments of the present disclosure.

FIG. 1 E depicts another embodiment of a substrate carrier assembly for covering substrate surfaces with porous Si in accordance with some embodiments of the present disclosure.

FIG. 2 depicts a chemical bath reaction tank including a plurality of substrate carrier assemblies for batch processing in accordance with some embodiments of the present disclosure.

FIG. 3 depicts a top view of a substrate holder in accordance with some embodiments of the present disclosure.

FIGS. 4 and 5 depict a process and dual sided substrate holder for fully covering substrate surfaces with porous Si in accordance with alternate embodiments of the present disclosure.

FIG. 6 depicts a transportation system that transports the plurality of substrates to the substrates holders in chemical bath in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation. In addition, in this document, relational terms such as first and second, top and bottom, front and back, and the like may be used solely to distinguish one entity or action from another entity or action without necessarily requiring or implying any actual such relationship or order between such entities or actions.

### DETAILED DESCRIPTION

Embodiments of high volume production porous Si manufacturing tools and methods are provided herein. In at least some embodiments, the inventive methods and apparatus disclosed herein may advantageously provide high throughput production of porous silicon layers at low cost with full porous silicon layer coverage over the entire substrate surface, which may include the front and back surface of the substrates as well as the substrate edge beveling area. In addition, embodiments consistent with the present disclosure advantageously enhance the manufacturability to grow one or more epitaxial layers on top of the porous Si layers on both sides of the template substrate simultaneously. As a result, embodiments of the present invention advantageously improve the epitaxial throughput which is a major part of the cost of ownership to produce PV epi-substrates. Furthermore, embodiments consistent with the present disclosure provide improved edge sealing methods which advantageously avoid the problems of inferior edge quality of the starting template substrates, as well as reclaiming cost reduction especially to remove the locked epitaxial residue at the apex of the substrate edge.

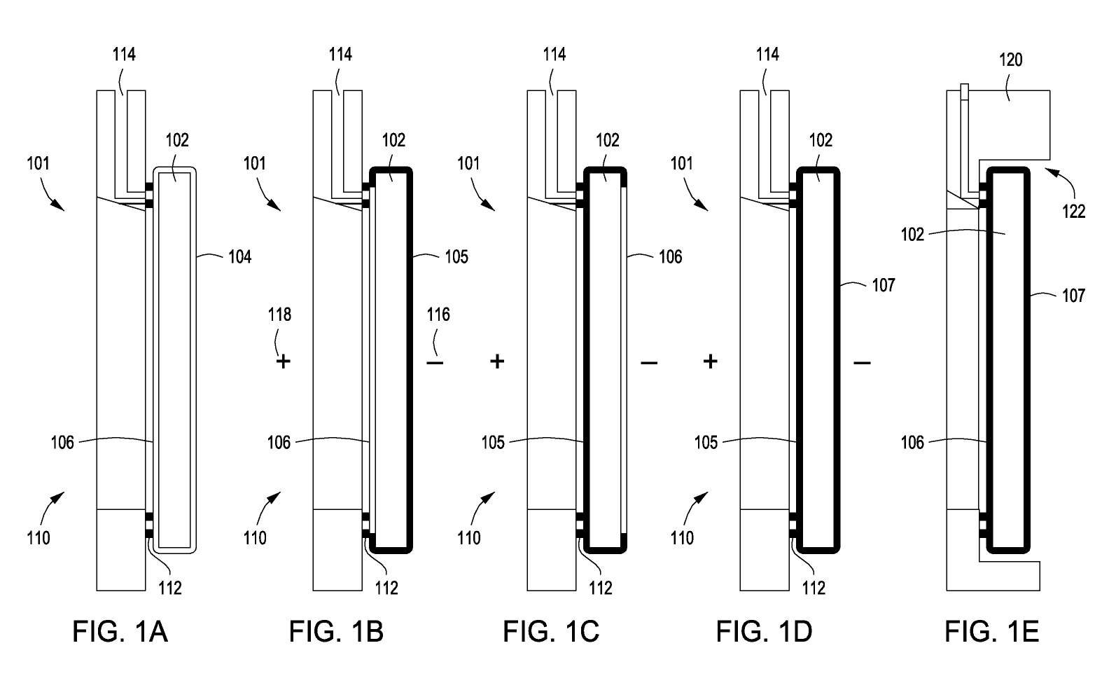

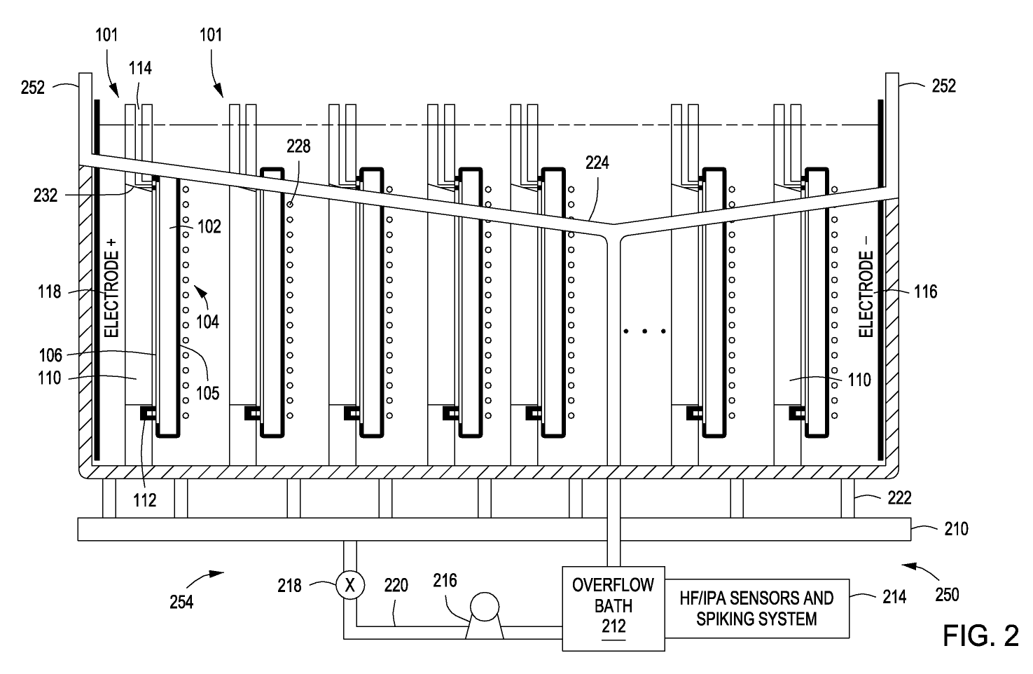

FIGS. 1A-1D depict a general overview of a process and substrate carrier assembly 101 for fully covering all substrate surfaces with porous Si. The process is also referred to as an All Wrap Around (AWA) Porous Silicon (Si) process. FIG. 1A depicts the substrate carrier assembly 101 which, in some embodiments, includes a substrate 102 disposed on a substrate holder 110 with back side sealing via one or more vacuum channels 114 of a vacuum chuck and sealing element 112. The vacuum channel 114 extends to a substrate supporting surface of the substrate holder 110. In some embodiments, the vacuum channel 114 is disposed about a periphery of the substrate support surface of substrate holder 110. The vacuum channel 114 is fluidly coupled to sealing element 112. The sealing element 112 supports and retains the substrate 102 through vacuum chucking forces. In some embodiments, and electrostatic chuck (ESC) may be used to retain the substrate via electrostatic forces instead of a vacuum chuck.

The substrate 102 and substrate holder 110 may be used in a processing chamber or chemical bath. The substrate 102 has a first surface 104, also referred to herein as a front surface that is initially exposed to the processing environment of the processing chamber or chemical bath. The substrate 102 also has a second surface 106, also referred to herein as a back surface that is initially not exposed to the processing environment of the processing chamber or chemical bath. FIG. 1A depicts the substrate 102 prior to any porous Si formation/anodization on either the front or back surfaces 104, 106.

In FIG. 1B, a porous Si layer 105 is formed on the exposed first surface 104 (i.e., the first surface 104 is anodized) creating a single sided porous Si substrate 102. In some embodiments, the porous Si layer 105 is formed on first surface 104 of the substrate 102 using a Hydrofluoric (HF) acid bath and exposing the first surface 104 of the substrate 102 to an electric charge via electrodes 116, 118. In some embodiments, the porous Si layer 105 is formed on the surface that is subjected to a negative charge via electrode 116 (e.g., a cathode or negatively charged electrode). In some embodiments, the porous Si layer 105 is formed on all exposed surfaces (e.g., front surfaces, side surfaces, and some backside surfaces near the edge of the substrate 102 beyond the sealing element 112).

In FIG. 1C, the single sided porous Si substrate 102 from FIG. 1B is placed with the un-anodized Si second surface 106 as the exposed surface (e.g., the substrate 102 is flipped/turned). In FIG. 1D, a porous Si layer 107 is formed on the exposed second surface 106 (i.e., the second surface 106 is anodized) creating a double sided porous Si substrate 102. In some embodiments, the porous Si layer 107 is formed on second surface 106 of the substrate 102 using the same process described above with respect to FIG. 1B.

In some embodiments, the front side and backside porous silicon formation occurs in different process tanks. The geometry of the holders for each tank may vary. Specifically, the substrate holder 110 shown in FIGS. 1A-1D may be used to form a porous Si layer 105 on the exposed first surface 104. In FIGS. 1A-1D, the substrate stands off from the holder, and the bevel of the substrate is exposed to allow current flow through the surface, causing porous silicon formation. However, in some embodiments, a second type of substrate holder 120 shown in FIG. 1E may be used in a second tank to form a porous Si layer 107 on the exposed second surface 106. In FIGS. 1E, the substrate 102 is recessed in a shallow pocket 122 such that current flow through the bevel is minimized. This prevents excessive porous silicon growth on the bevel of the substrate.

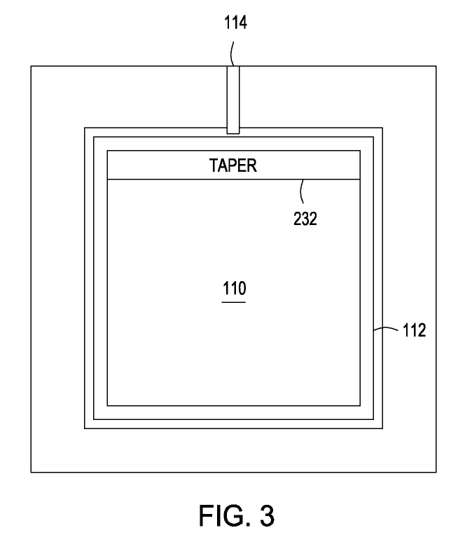

FIG. 2 depicts an electrochemical reaction tank 100 (also referred to herein as a process chamber or reaction tank) including a plurality of substrate carrier assemblies 101 for batch processing. In some embodiments, the substrates 102 are p-type or P++ Si substrates. In some embodiments, the substrate p-type dopant used for the substrate has a boron volume of over 1e7-8/cm3. In some embodiments, the substrates 102 may be square or circular shaped substrates. The substrates 102 are placed on the holders 110 in a liquid chemical solution 230 in the anodizing electrochemical reaction tank 100 by vacuum chucking on the back side of the substrates 102. In some embodiments, the chemical solution the in the electrochemical reaction tank 100 may be formed from HF, isopropyl alcohol (IPA), and/or H2O. In some embodiments, other solutions may be used for anodization/porous Si formation, such as, for example, HF/Ethanol/deionized water (DIW), HF/Acetic Acid/DIW, HF/IPA, or HF/Ethanol.

The substrate holder 110 includes a tapered opening 232 to the chemical solution 230 which advantageously allows for the hydrogen byproduct gas 228 to release efficiently upward in the chemical solution vaporizing into the air to assist in preventing the hydrogen byproduct gas 228 from blocking the anodic current flow which can cause non-uniform porous Si layers. The hydrogen byproduct gas 228 bubbles are efficiently released by overflowing the chemical solution 230 and circulating in the chemical solution 230 during anodizing as shown in FIG. 2. The anodic current is provided by the two electrodes 116, 118. In some embodiments, the electrodes 116, 118 may be formed from platinum (Pt). In other embodiments, the electrodes 116, 118 may be formed from diamond or diamond-like carbon coated doped silicon, or a Boron-doped diamond film with metallic back plate. The electrodes 116, 118 may be located at the both ends of the electrochemical reaction tank 100 in DC and/or AC. The Si substrate surface that is exposed to the negative electrode reacts with HF to remove (i.e., etch) Si atoms. The etching process leaves nanometer sized vacancies referred to as pores. The hydrogen byproduct gas 228 is the bi-product of the anodic reaction over the Si substrate surface as shown in FIG. 2. In some embodiments, the desired pore thickness, pore density (porosity), and pore size formed on the anodized substrate surfaces (e.g., 105 and 107) may be uniformly formed on the each Si substrates by controlling the anodic current running through all the substrates located in between the two electrodes 116, 118. In some embodiments, each of the substrates 102 may be electrically isolated from each other by sealing element 112 to help control the anodic current running through all the substrates located in between the two electrodes 116, 118. The nonconductive sealing element 112 prefers fluid transfer between each segment of the tank, preventing current from bypassing the wafer. That is, identical porous Si layers may be formed on each Si substrates by controlling the anodic current running through all the substrates located in between the two electrodes 116, 118. In some embodiments, the porous Si layers may be formed on the back sides of each substrate by reversing the directional current. Changing the anodic current or modulating the current enables the formation of multiple layers of porous Si that is normally used for the separation layer to exfoliate the epitaxial layers on top of the Porous Si layer.

As shown in FIG. 2, a plurality of substrate carrier assemblies 101, each including a substrate 102 and substrate holder 110, are disposed in the anodic bath (i.e., chemical solution 230). The same current is provided through all the substrates 102 which are isolated electrically from each other by sealing, via sealing element 112, at the each substrate holder 110. The sealing element 112 may be formed from electrically insulative material. As a result, the porous Si layers 105, 107 are formed on the substrates 102 on the surface toward to the negative electrode 116 as well as the substrate edge area including the tapered opening 232. In some embodiments, small portions of the back side of the silicon substrates (i.e., the substrate surface facing the positive electrode 118) are anodized to form a porous Si layer.

The hydrogen byproduct gas 228 bubbles are formed as bi-product of the electrochemical reaction in between HF and Si on both sides of the substrates, producing hydrogen gas on the substrate surfaces. In some embodiments, the hydrogen byproduct gas 228 bubbles are accumulated at the corner of the upper interface between the substrate holder 110 edge and the substrates 102. The accumulated hydrogen byproduct gas 228 bubbles agglomerate into the bigger bubbles, which shadow the current flow, resulting in thinner porous silicon with lower density of pores due to the insufficient charges that are supplied due to the shadowing effect induced the hydrogen gas accumulation. In order to decrease the problem caused by the hydrogen byproduct gas 228 bubbles, one side of the substrate holder 110 is a tapered opening 232. The tapered opening 232 at the upper part of the substrate holder 110 allows for more efficient ventilation of the hydrogen byproduct gas 228 bubbles.

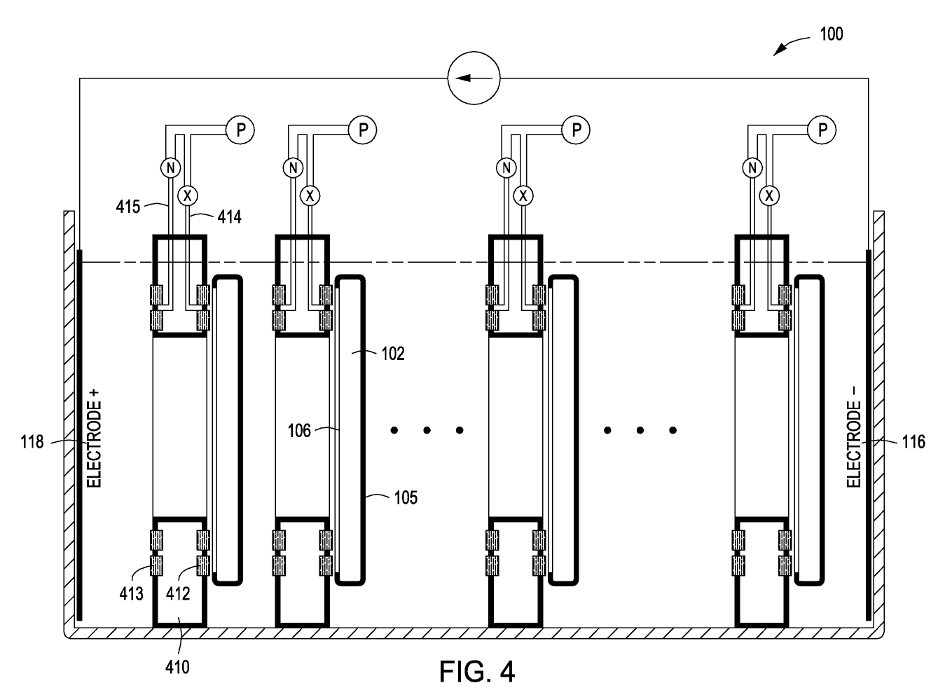

FIG. 3 depicts a top view of a substrate holder 110 include sealing element 112, vacuum channel 114 and showing the tapered opening 232. In some embodiments, the sealing element 112 may be a dual sealing ring (e.g., double O-rings or Flat-rings) as shown in FIG. 3. Although FIG. 3 depicts a square substrate holder 110 for holding square substrates, other shaped substrate holders 110 and substrates may be used with matching sealing element (e.g., circular substrates and holders, etc.)

In other embodiments, the sealing element 112 is a dual ring of polymer or elastomer foam. An elastomer foam seal has the advantage over elastomer 0-ring seals in that the elastomer foam seal requires low compression force and thus less vacuum surface area. The entire seal can be contained in the edge exclusion area of the substrate, which is not used for the solar cell. This leads to lower EPI defect levels in active area. Also, the small geometry seal reduces the current masking effect of the holder, so that substrate can be placed closer together in the bath while maintaining uniform current distribution.

In some embodiments, a chemical overflow system 250 is included in the electrochemical reaction tank 100 to address issues caused by the accumulated hydrogen byproduct gas 228 bubbles. The chemical overflow system 250 includes an overflow receptor 224 that has inlets 252 disposed in various locations within the electrochemical reaction tank 100. The overflow receptor 224 collects the overflow reaction chemicals and funnels them to an overflow bath 212. In some embodiments, the overflow receptor is located well underneath the bath. Overflow streams from each segment of the bath remain isolated as they overflow the bath and fall to the receptor. This minimizes leakage current paths between bath segments and electrodes through the overflow receptor. The overflow reaction chemicals are monitored and treated to the proper chemical compositional levels (discussed below) and returned by a resistive pumping system 254 back into the chemical solution 230 from the bottom of the electrochemical reaction tank 100 through the manifold 210. In some embodiments, the resistive pumping system 254 includes pump 216, valve 218, conduits 220, manifold 210 and conduits 222. A HF/IPA sensor and spiking system 214 is used to control the HF/IPA chemical compositional ratio. The HF/IPA sensor and spiking system 214 includes sensing monitors that monitor the chemical solution 230 and overflow bath 212. Based on the monitored chemical levels of the chemical solution 230 and/or the overflow bath 212, the HF/IPA sensor and spiking system 214 will supply the necessary chemical components to keep the chemical solution 230 and/or the overflow bath 212 chemistry at desired levels to form the uniform porous Si layers. This resistive pumping system 254 is also used for dumping the chemical from the bath when the substrates are loaded and unloaded in the electrochemical reaction tank 100.

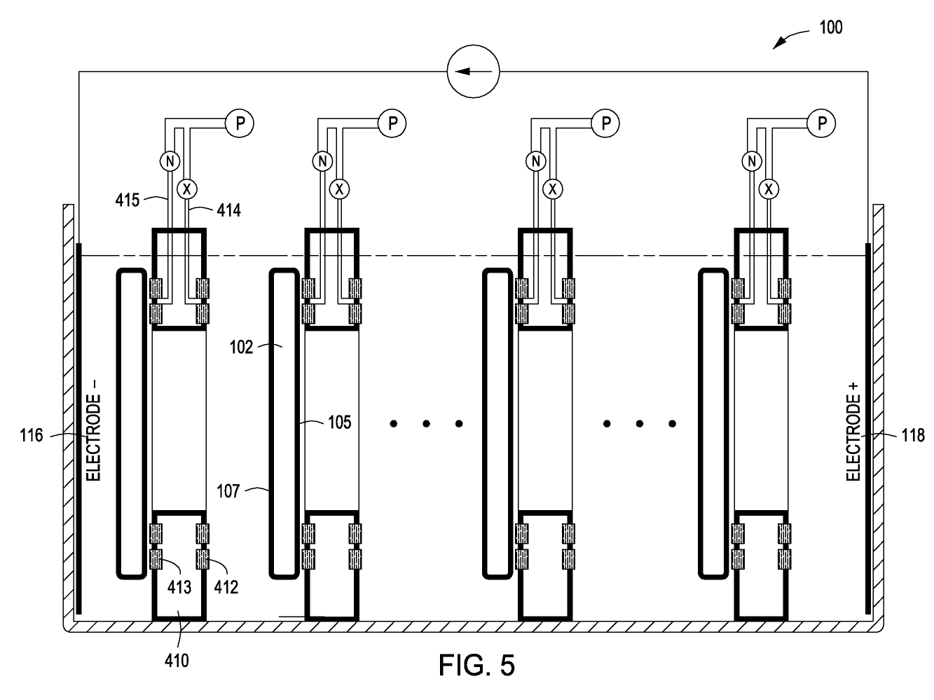

In some embodiments, instead of flipping the substrate 102 on holder 110, a dual sided substrate holder 410 may be used as shown in FIGS. 4 and 5. The dual sided substrate holder 410 includes sealing elements 412, 413 on each side of the holder. Each of the sealing elements 412, 413 is coupled to a vacuum channel 414, 415 to provide vacuum chucking forces to retain the substrate 102. In this way, a porous Si layer 105 is formed on the exposed first surface (e.g., the side facing negative electrode 118) as shown in FIG. 4. In FIG. 5, the substrate 102 is moved to the other side of the dual sided substrate holder 410, and the polarity of the electrodes 116, 118 are reversed such that the negative electrode is shown on the left in FIG. 5. The dual sided substrate holder 410 provides dual sided vacuum chucking that can be independently operated and the substrates are placed on the right hand holder first to form the single sided porous silicon layer on the front of the substrates facing toward the negative electrode 116. The anodized substrates are un-chucked and lifted by the robot fingers, shifted toward onto the other side of the holder where another chucking system is equipped. When changing the polarity for the electrode, the second surface of the substrates is anodized to form the porous Si layers as shown in FIG. 5.

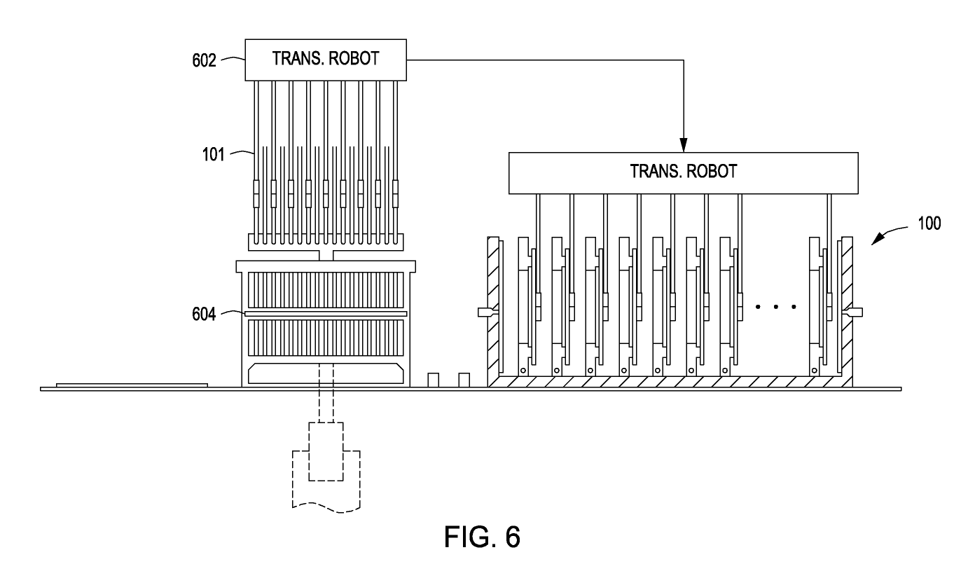

FIG. 6 depicts a transportation system 600 that transports the plurality of substrates 102 to the substrates holders 110 in electrochemical reaction tank 100. All the substrates 102 are lifted up from the carrier 604 by the transport robot 602. Each substrate has to be held by fingers of the transport robot 602, however the multiple substrates are simultaneously transferred into the bath for increasing the throughput.

In some embodiments, the transport system includes a set of compliant end effectors for holding the wafers. The compliant end effectors are self-aligning to features in the substrate holders. This enables tight positional accuracy of the wafer to both the seal, to ensure good sealing, and to the walls of the bath, to ensure uniform current flow through the bevel of the substrate. This leads to uniform porous silicon formation around the bevel of the substrate. The complaint end effectors enable to same loader to load multiple baths or multiple positions in the same bath without a cumbersome alignment procedure.

In some embodiments, the substrate holder 110 includes a section of flexible diaphragm outside the seals. This flexible section allows the end effector to press the substrate into the seal and ensure the seal surface can comply to the flat surface of the substrate. In some versions of this embodiment, a rigid plate presses the backside of the holder during loading forcing the sealing surface flat against the substrate. In embodiments of the seal with compliant foam, the large compression of the foam ensures compliance of the seal during loading.

While the foregoing is directed to embodiments of the present invention, other and further embodiments of the invention may be devised without departing from the basic scope thereof.

1. A substrate holder, comprising:
a body having a tapered opening along a first edge of the body, wherein the tapered opening is configured to release byproduct gases produced during porous silicon formation on a substrate supported by the substrate holder;
a first vacuum channel formed in the body and extending to a first surface of the body; and
a first sealing element disposed on the first surface of the body and fluidly coupled to the first vacuum channel, where in the first sealing element supports the substrate when disposed thereon.

2. The substrate holder of claim 1, wherein the sealing element is a dual sealing ring.

3. The substrate holder of claim 2, wherein the sealing element is a double 0-ring or double flat-ring.

4. The substrate holder of claim 1, wherein the sealing element is formed from electrically insulating material.

5. The substrate holder of claim 1, wherein the sealing element retains the substrate when disposed thereon through vacuum chucking forces.

6. The substrate holder of claim 5, wherein the substrate holder is configured to retain the substrate in a vertical position.

7. The substrate holder of any of claims claim 1-5, wherein the first surface of the body has a square profile to support square substrates, and wherein the sealing element is a double flat-ring have a square profile.

8. The substrate holder of any of claims claim 1-5, wherein the first surface of the body has a circular profile to support circular substrates, and wherein the sealing element is a double O-ring have a circular profile.

9. The substrate holder of any of claims claim 1-5, further comprising:
a second vacuum channel formed in the body and extending to a second surface of the body opposite the first surface; and
a second sealing element disposed on the second surface of the body and fluidly coupled to the second vacuum channel, where in the second sealing element supports the substrate when disposed thereon.

10. An electrochemical reaction system, comprising:
a reaction tank configured to hold a liquid chemical solution to anodize one or more substrates;
a plurality of substrate holders disposed in the reaction tank, each holder configured to retain a substrate when disposed thereon via vacuum chucking forces;
a first electrode disposed at a first end of the reaction tank;
a second electrode disposed at a second end of the reaction tank opposite the first end; and
a chemical overflow system configured to collect overflow reaction chemicals during substrate processing.

11. The electrochemical reaction system of claim 10, wherein each substrate holder comprises:
a body having a tapered opening on a first edge of the body configured to release byproduct gases produced during processing;
a vacuum channel formed in the body and extending to a first surface of the body; and
a sealing element disposed on the first surface of the body and fluidly coupled to the vacuum channel, where in the sealing element supports a substrate when disposed thereon.

12. The electrochemical reaction system of claim 10, wherein the chemical overflow system comprises:
an overflow receptor having a plurality of inlets disposed in the reaction tank configured to receive overflow reaction chemicals;
an overflow bath coupled to the overflow receptor; and
a resistive pumping system coupled to the overflow bath and the reaction tank.

13. The electrochemical reaction system of claim 12, wherein the resistive pumping system is configured to pump treated overflow reaction chemicals back into the reaction tank.

14. The electrochemical reaction system of claim 12, wherein the chemical overflow system further comprises a chemical sensor and spiking system configured to monitor and control chemical compositional levels of the liquid chemical solution and the overflow reaction chemicals.

15. A method for all wrap around porous silicon formation, comprising:
disposing a plurality of silicon substrates onto a corresponding plurality of substrate holders disposed in a reaction tank filled with a hydrogen fluoride (HF) solution of a electrochemical reaction system;
retaining each of the plurality of silicon substrates on a first side of a corresponding substrate holder via vacuum chucking;
providing a current through the hydrogen fluoride (HF) solution using a positive and negative electrode disposed in the reaction tank;
forming a first porous silicon layer on a first surface each of the plurality of silicon substrates, where the first surface of the silicon substrate faces the negative electrode;
repositioning each of the plurality of silicon substrates to expose a second surface of the silicon substrates to the negative electrode; and
forming a second porous silicon layer on a second surface of the silicon substrate.

16. The method of claim 15, wherein each of the plurality of silicon substrates are flipped to expose the second surface of the silicon substrates to the negative electrode after forming the first porous silicon layer, such that the substrate is retained on the same side of the substrate holder while the second porous silicon layer is formed.

17. The method of claim 15, wherein after the first porous silicon layer is formed, the polarity of the positive and negative electrodes are reversed and the plurality of silicon substrates are moved to an opposite side of the substrate holder to expose the second surface of the silicon substrates to the negative electrode while the second porous silicon layer is formed.

18. The electrochemical reaction system of claim 12, wherein the chemical overflow system is further configured to remove the liquid chemical solution and the overflow reaction chemicals from the reaction tank after the substrate has been processed.

19. The electrochemical reaction system of claim 10, further comprising:
a substrate transportation system comprising a plurality of mechanical fingers, each finger configured to pick up the one or more substrates along a peripheral edge, wherein the substrate transportation system is configured to transport a plurality of substrates onto the corresponding plurality of substrate holders disposed in the reaction tank.

20. The electrochemical reaction system of claim 10, wherein the liquid chemical solution is a hydrogen fluoride (HF) solution, and wherein the electrochemical reaction system is configured to form porous silicon on all sides of one or more substrates when disposed there.
